(19) United States
(12) Patent Application Publication
(10) Pub. No.: US 2025/0118945 A1
(43) Pub. Date: Apr. 10, 2025

(54) APPARATUS FOR HEATING FLAT SUBSTRATE USING VCSEL MODULE

(71) Applicant: Viatron Technologies, Inc., Gyeonggi-do (KR)

(72) Inventors: Hyoung June Kim, Seoul (KR); Byung Kuk Kim, Gyeonggi-do (KR); Wang Jun Park, Gyeonggi-do (KR); June Hee Lee, Gyeonggi-do (KR)

(21) Appl. No.: 18/722,435

(22) PCT Filed: Dec. 28, 2022
(86) PCT No.: PCT/KR2022/021504

§ 371 Date: Dec. 24, 2024

(30) Foreign Application Priority Data
Dec. 30, 2021 (KR) 10-2021-0192844

(51) Int. Cl. H01S 5/024; H01S 5/183; H01S 5/42

(52) U.S. Cl. CPC H01S 5/02423; H01S 5/183; H01S 5/423

(57) ABSTRACT

The present disclosure discloses a flat-substrate heating apparatus including a module supporting plate having a plurality of unit module regions formed on an upper surface thereof; a plurality of VCSEL modules having a plurality of VCSEL devices and seated on the unit module regions of the module support plate, respectively; an electric power supplying board placed below the module support plate and configured to supply an electric power to the VCSEL module; and an electrode terminal electrically connecting the VCSEL module and the electric power supplying board while detachably securing them to upper and lower surfaces of the module support plate, wherein the module support plate has a coolant supplying unit formed therein and configured to supply coolant to the VCSEL module.

### TECHNICAL FIELD

The present disclosure relates to a flat-substrate heating apparatus for heating a flat substrate, such as a semiconductor wafer or a glass substrate, using a VCSEL module.

### BACKGROUND ART

A flat substrate such as a semiconductor wafer or a glass substrate may undergo a heat treatment process such as a silicon thin film crystallization process, an ion implantation process, and an activation process. The above heat treatment process is generally carried out using a halogen lamp-heating apparatus including a halogen lamp as a light source.

The halogen lamp-heating apparatus has a structure by which light is irradiated to a front surface or a rear surface of the flat substrate and the light is irradiated back to the flat substrate using a reflector. Therefore, the halogen lamp-heating apparatus has an aspect that a flash lamp arrangement structure and a reflector structure become complicated in order to increase temperature uniformity of the flat substrate. In addition, the halogen lamp-heating apparatus has the aspect that the maintenance cost for the apparatus is increased due to the short lifespan of the halogen lamp.

Recently, a flat-substrate heating apparatus using a VCSEL (vertical cavity surface emitting laser) has been developed. The flat-substrate heating apparatus using the VCSEL is formed such that a VCSLE module including a plurality of VCSELs is arranged in a planar shape to irradiate a laser beam to a region having a large area. The flat-substrate heating apparatus using the VCSEL should independently supply an electric power to each VCSEL module, so the number of electric power lines is increased and wiring becomes complicated. In addition, the flat-substrate heating apparatus using the VCSEL has a problem in that when one of the VCSELs is broken, it is difficult to separate the problematic VCSEL module and the electric power line from each other. Also, the flat-substrate heating apparatus using the VCSEL needs to supply cooling water to each VCSEL module, but the flat-substrate heating apparatus may be formed to be complicated in structure because of electric power lines. Furthermore, the flat-substrate heating apparatus using the VCSEL has a problem in that the number of electric power lines and the number of structural components per unit area are increased, which takes a lot of time to execute repair.

### DISCLOSURE OF THE INVENTION

### Technical Problem

An object of the present disclosure is to provide a flat-substrate heating apparatus including a VCSEL module, which, due to a reduction of the number of electric power lines and components, has a simple structure and performs an efficient maintenance.

### Technical Solution

A flat-substrate heating apparatus of the present disclosure includes a module supporting plate having a plurality of unit module regions formed on an upper surface thereof; a plurality of VCSEL modules having a plurality of VCSEL devices and seated on the unit module regions of the module support plate, respectively; an electric power supplying board placed below the module support plate and configured to supply an electric power to the VCSEL module; and an electrode terminal electrically connecting the VCSEL module and the electric power supplying board while detachably securing them to upper and lower surfaces of the module support plate, wherein the module support plate has a coolant supplying unit formed therein and configured to supply coolant to the VCSEL module.

Also, the VCSEL module may include a device substrate having a device region, a terminal region, and a device terminal hole passing through the terminal region from an upper surface to a lower surface of the terminal area; a VCSEL device arranged on the device region of the device substrate; a terminal pad formed in a ring shape along extending along an outer periphery of an upper end of the device terminal hole; and a cooling block placed below the device substrate and having a block terminal hole.

In addition, the module support plate may have a support main body plate having a support terminal hole formed at a position corresponding to the device terminal hole in the unit module region, the electric power supplying board may have an electric power terminal hole formed at a position corresponding to the support terminal hole, and the electrode terminal may include an upper terminal bolt passing through the device terminal hole and the block terminal hole to be inserted into an upper portion of the support terminal hole, a lower terminal bolt passing through the electric power terminal hole to be inserted into a lower portion of the support terminal hole, and a connecting nut placed inside the support terminal hole to be screw-coupled with the upper terminal bolt and the lower terminal bolt.

Furthermore, the upper terminal bolt may be electrically connected to the terminal pad, and the lower terminal bolt is electrically connected to the electric power supplying board.

Also, the electrode terminal may further include an insulating tube placed between an inner circumferential surface of the support terminal hole and an outer circumferential surface of the connecting nut.

In addition, the coolant supplying unit may include a main body internal flow passage formed to extend horizontally in a x-axial direction or a y-axial direction within the support main body plate; a main body upper flow passage extending vertically within the support main body plate, a lower end of which being connected to the main body internal flow passage and an upper end of which being is opened to an upper surface of the support main body plate; and a main body lower flow passage extending vertically within the support main body plate, an upper end of which being connected to the main body internal passage, and a lower end of which being opened to a lower surface of the support main plate, and the cooling block may further include a block cooling flow passage being in communication with the main body upper flow passage, and may be formed such that coolant for cooling the VCSEL device flows through the main body upper flow passage and the block cooling flow passage.

Furthermore, the coolant supplying unit may further include a coolant inlet tube for supplying coolant to the main body lower flow passage, and a coolant outlet tube for discharging coolant from the main body lower flow passage.

Also, the support main body plate may further include a connecting flow passage connecting the main body internal flow passages when the plurality of main body internal flow passages are formed in plurality of pairs.

### Advantageous Effects

In the flat-substrate heating apparatus of the present disclosure, the coolant flow passage for supplying coolant to the plurality of VCSEL modules are formed in the module support plate supporting the VCSEL modules, so a separate coolant supplying module is not required and the overall structure can be simplified.

In addition, in the flat-substrate heating apparatus of the present disclosure, as the overall structure of the apparatus is simplified, a process for forming the coolant flow passage can be reduced and maintenance can be facilitated.

Furthermore, in the flat-substrate heating apparatus of the present disclosure, the number of connection parts between the components for the coolant flow passage is reduced, thereby reducing the possibility of coolant leakage.

In addition, the flat-substrate heating apparatus of the present disclosure, since each VCSEL module is connected to the modular electrode board through the module support plate using the electrode terminal which can be separately from above and below, it is possible to more easily separate the broken VCSEL module.

The flat-substrate heating apparatus of the present disclosure supplies an electric power to each VCSEL module using the electrode terminal and the electric power supplying board to eliminate the electric power lines, thereby performing an efficient maintenance.

In addition, the flat-substrate heating apparatus of the present disclosure, coolant is supplied to each VCSEL module through the support coolant hole and the protrusion coolant hole formed independently in the module support plate made of metal, so the coolant flow passage is simplified, and maintenance can be carried out efficiently.

Furthermore, in the flat-substrate heating apparatus of the present disclosure, the flow passage for supplying coolant to each VCSEL module is formed, so it is possible to easily and independently separate the broken VCSEL module.

### BRIEF DESCRIPTION OF THE DRAWINGS

FIG. 1 is an exploded perspective view of a flat-substrate heating apparatus having a VCSEL module according to one embodiment of the present disclosure;

FIG. 2 is a vertical cross-sectional view of the flat-substrate heating apparatus of FIG. 1 in an assembled state;

FIG. 3 is a partial enlarged view of “A” in FIG. 2;

FIG. 4 is a vertical cross-sectional view of the flat-substrate heating apparatus of FIG. 1 in an assembled state viewed from a different location;

FIG. 5 is a partially enlarged vertical cross-sectional view of “B” in FIG. 4;

FIG. 6 is a partial vertical cross-sectional view showing a connection relation of a coolant flow passage in a support main body plate and the VCSEL module of FIG. 1;

FIG. 7 is a partial perspective view of the VCSEL module of FIG. 1;

FIG. 8 is a vertical cross-sectional view taken along line “A-A” of a VCSEL module of FIG. 7; and

FIG. 9 is a plan view of an electric power supplying board of FIG. 1.

### BEST MODE FOR CARRYING OUT THE INVENTION

Hereinafter, a flat-substrate heating apparatus having a VCSEL module of the present disclosure is described in detail with reference to embodiments and the accompanying drawings.

First, a configuration of flat-substrate heating apparatus having a VCSEL module according to the present disclosure is described.

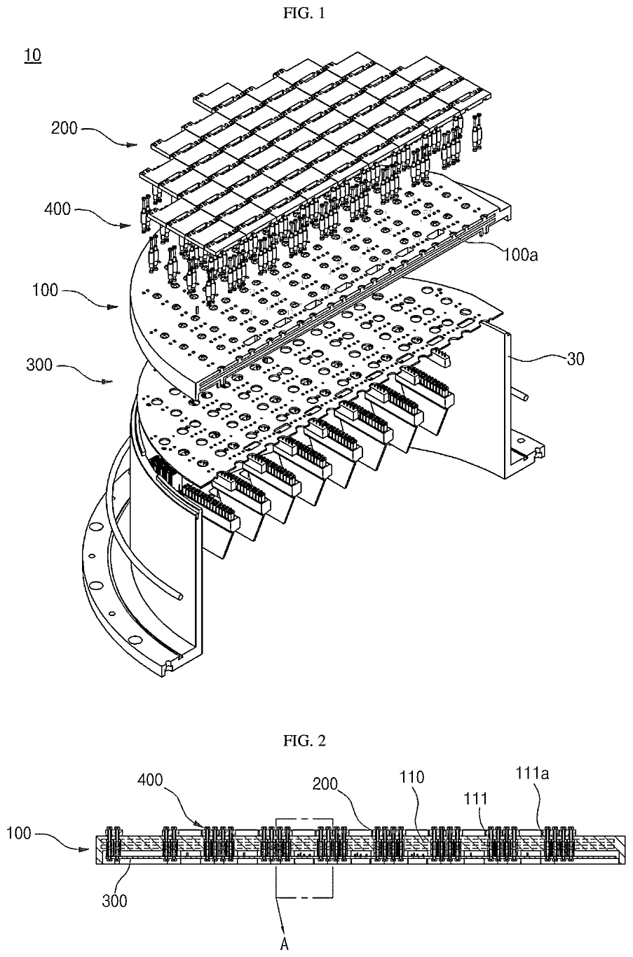

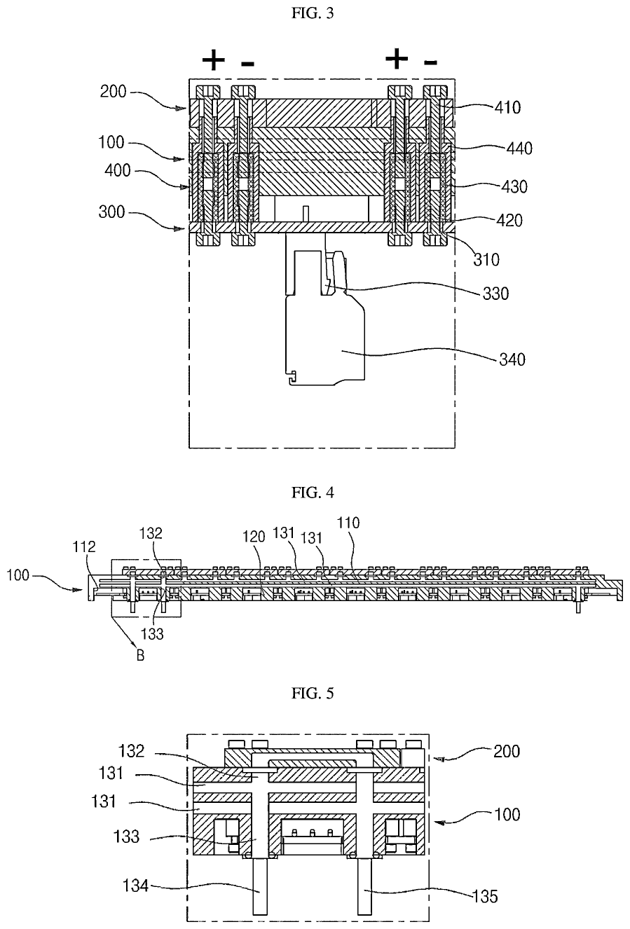

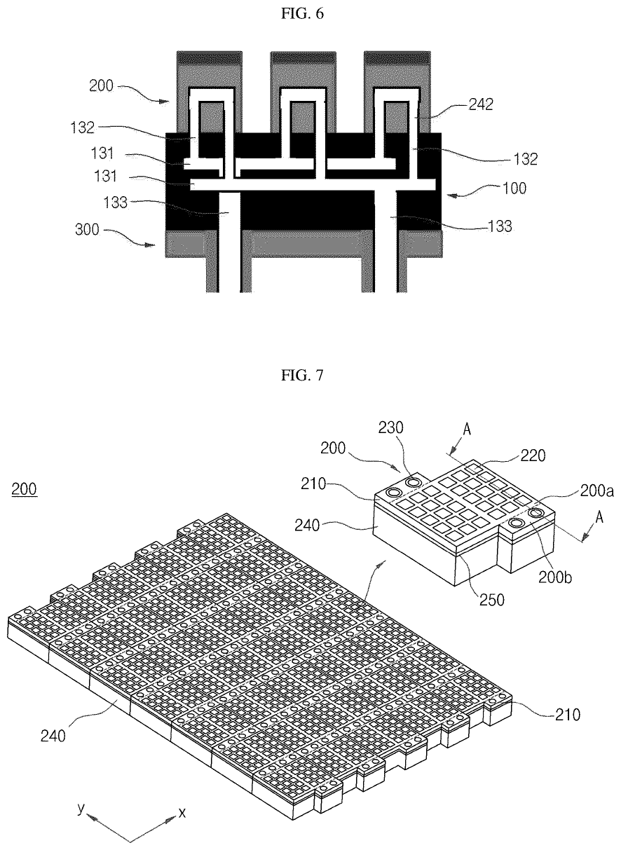

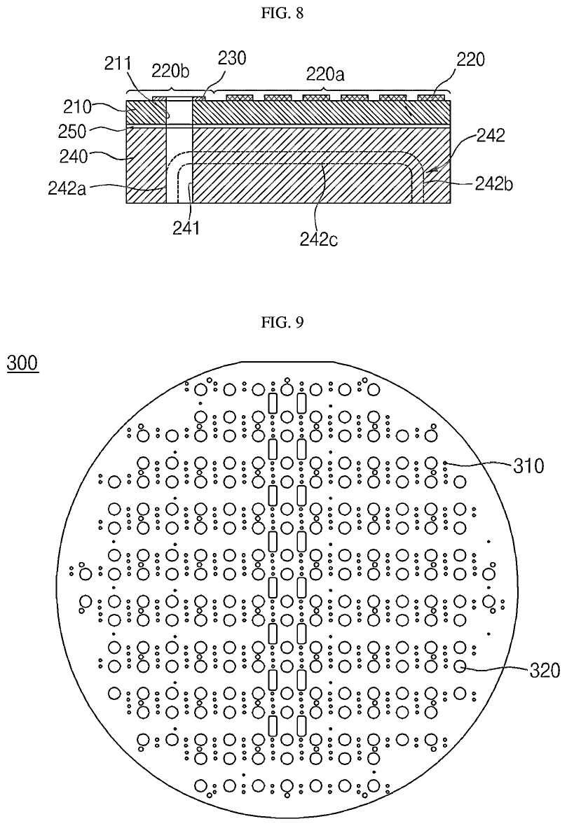

FIG. 1 is an exploded perspective view of a flat-substrate heating apparatus including having a VCSEL module according to one embodiment of the present disclosure. FIG. 2 is a vertical cross-sectional view of the flat-substrate heating apparatus of FIG. 1 in an assembled state. FIG. 3 is a partial enlarged view of “A” in FIG. 2. FIG. 4 is a vertical cross-sectional view of the flat-substrate heating apparatus of FIG. 1 in an assembled state viewed from a different location. FIG. 5 is a partially enlarged vertical cross-sectional view of “B” in FIG. 4. FIG. 6 is a partial vertical cross-sectional view showing a connection relation of a coolant flow passage in a support main body plate and the VCSEL module of FIG. 1. FIG. 7 is a partial perspective view of the VCSEL module of FIG. 1. FIG. 8 is a vertical cross-sectional view taken along line “A-A” of a VCSEL module of FIG. 7. FIG. 9 is a plan view of an electric power supplying board of FIG. 1.

Referring to FIGS. 1 to 9, a flat-substrate heating apparatus 10 according to one embodiment of the present disclosure may include a module supporting plate 100, a VCSEL module 200, an electric power supplying board 300 and electrode terminals 400.

In FIG. 1, meanwhile, reference numeral 30, which is not described above, designates an internal housing which forms a heat treatment chamber in a heat treatment apparatus including the flat-substrate heating apparatus 10 and is provided for supporting the flat-substrate heating apparatus 10.

In the flat-substrate heating apparatus 100, the VCSEL module 200 is placed above the module supporting plate 100, and the electric power supplying board 300 is placed below the module supporting plate 100. In the flat-substrate heating apparatus 10, in addition, the VCSEL module 200 and the electric power supplying board 300 are physically secured to the module supporting plate 100 by the electrode terminals 400. At this time, in the flat-substrate heating apparatus 10, the VCSEL module 200 disposed above the module supporting plate 100 and the electric power supplying board 300 disposed below the module supporting plate 100 are secured and electrically connected to each other by the electrode terminals 400.

In the flat-substrate heating apparatus 10, therefore, an electric power is supplied from the electric power supplying substrate 300 to the VCSEL module 200 through the electrode terminals 400. In the flat-substrate heating apparatus 10, the VCSEL module 200 may be detached from the module supporting plate 100 by separating the electrode terminals 400.

The flat-substrate heating apparatus 10 may irradiate a laser beam generated from the VCSEL module 20 to a flat substrate placed thereabove to heat the flat substrate. Here, the flat substrate may be a semiconductor wafer or a glass substrate. In addition, the flat substrate may be a flexible substrate such as a resin film. Furthermore, the flat substrate may include various elements or electrically conductive patterns formed therein or on a surface thereof.

The flat-substrate heating apparatus 10 is applicable to a heating apparatus in which a manufacturing process such as a silicon thin layer crystallization process, an ion implantation process, or an activation process for the flat substrate is performed.

The module supporting plate 100 may include a support main body plate 110 and a support lower protrusion 120. In addition, the module supporting plate 100 may further include a coolant supplying unit 130. The module supporting plate 100 may be formed as a circular plate or a square plate. The module supporting plate 100 may be formed in a circular plate shape when the flat substrate is a semiconductor wafer. Also, the module supporting plate 100 may be formed in a square plate shape when the flat substrate is a glass substrate.

The module supporting plate 100 may be divided into a plurality of unit module regions 100a. The unit module region 100a is a region on which each VCSEL module 200 is seated. The unit module regions 100a may be placed arranged to be adjacent to each other in a lattice arrangement. Accordingly, the plurality of unit module regions 100a may be placed to be adjacent to each other in a length direction and a width direction.

The support main body plate 110 may include support terminal holes 111 and substrate supporting grooves 112. The support main body plate 110 may be formed in a circular plate shape with a predetermined thickness. In addition, the support main body plate 110 may be made from metallic material having mechanical strength and thermal conductivity. For example, the support main body plate 110 may be made from of a stainless-steel material or an aluminum material. The support main body plate 110 may be divided into the plurality of unit module regions 100a. Since each VCSEL module 200 is placed on the unit module region 100a, the electrode terminals 400 may be inserted into the pair of support terminal holes 111, respectively. Here, the electrode terminals 400 may be a positive electrode terminal and a negative electrode terminal.

The support terminal hole 111 may be formed by penetrating from an upper surface to a lower surface of the support main body plate 110. A pair of the support terminal holes 111 may be formed in each unit module region 100a. In other words, two support terminal holes 111 may be formed in pairs. The support terminal holes 111 may be formed in an appropriate number of pairs depending on a structure of the VCSEL module 200. For example, one pair or two pairs of the support terminal holes 111 may be formed in the unit module region 100a. When formed in two or more pairs, the support terminal holes 111 may be placed to be spaced apart from each other in a width direction or a diagonal direction in the unit module region 100a.

The support terminal hole 111 may include an insulating support ring 111a. The insulating support ring is formed in a ring shape that protrudes inward from an upper portion of the support terminal hole 111. An inner diameter of the insulating support ring 111a is smaller than that of the support terminal hole 111.

The substrate supporting groove 112 is formed with a predetermined depth from a lower surface of the support main body plate 110 in an upward direction. The plurality of the substrate supporting grooves 112 may be formed and dispersed in the support main body plate 110. The substrate supporting groove 112 may provide a passage to which a board fixing bolt, which is provided for fixing the electric power supplying board 300 to the module supporting plate 10, is coupled.

On a lower surface of the support main body plate 110, the support lower protrusion 120 is formed in a ring shape with a predetermined height. The support lower protrusion 120 may be formed integrally with the support main body plate 110. The support lower protrusions 120 are formed in pairs, one of which may provide a passage through which coolant inflows, and the other may provide a passage through which coolant flows out.

The coolant supplying unit 130 may include a main body internal flow passage 131, a main body upper flow passage 132, and a main body lower flow passage 133. In addition, the coolant supplying unit 130 may further include a coolant inlet tube 134 and a coolant outlet tube 135.

The coolant supplying unit 130 is placed inside the support main body plate 110 and may supply coolant to the VCSEL module 200. The coolant supplying unit 130 supplies coolant, which is supplied into the main body internal passage through the coolant inlet tube 134, to the VCSEL module 200. Also, the coolant supplying unit 130 discharges coolant, which flows thereinto from the VCSEL module 200 to the outside through the coolant outlet tube 135.

The main body internal flow passage 131 is formed to extend horizontally in a x-axial direction or a y-axial direction inside the support main body plate 110. The plurality of main body internal flow passages 131, which extend parallel to each other, may be formed. In addition, an appropriate number of the main body internal flow passages 131 may be formed depending on an area of the support main body plate 110. The main body internal flow passage 131 extends along an arrangement direction of the VCSEL devices 220 of the VCSEL module 200 placed thereabove. For example, the main body internal flow passage 131 may extend in the x-axial direction or the y-axial direction.

The two main body internal flow passages 131 extend parallel to each other may be formed in pairs. Accordingly, the main body internal flow passage 131 may form a supply flow passage through which coolant supplied to the VCSEL device 220 flows, and a drain flow passage through which coolant drained from the VCSEL device 220 flows. The supply flow passage and the drain flow passage of the main body internal flow passage 131 may be formed at different vertical heights within the support main body plate 110. Meanwhile, the supply flow passage and the drain flow passage of the main body internal flow passage may be connected to the supply flow passage and the drain flow passage of the main body internal flow passage of different adjacent pairs, respectively, by separate connection flow passages (not shown).

The main body upper flow passage 132 extends vertically inside the support main body plate 110, and is formed to be opened from the main body internal flow passage 131 to an upper surface of the support main body plate 110. In the main body upper flow passage 132, that is, a lower end may be connected to the main body internal flow passage 131 and an upper end may be opened to an upper surface of the support main body plate 110.

At least two main body upper flow passages 132 are placed to be spaced apart from each other in the unit module region 100a. The main body upper flow passage 132 is a passage through which coolant, which is used for cooling the VCSEL module 200 placed thereabove, flows.

The plurality of main body upper flow passages 132 may be formed and spaced apart from each other in an extension direction of the main body internal flow passage 131. That is, the main body upper flow passages 132 may be formed and spaced apart in an arrangement direction of the VCSEL devices 220. Also, a pair of the main body upper flow passages 132 may be formed in the main body internal flow passages 131 formed in one pair, respectively. In addition, the main body upper flow passages 132 may be formed in at least one pair to correspond to the main body internal flow passages 131. The main body upper flow passage 132 may independently supply coolant to each VCSEL module 200. In addition, the main body upper flow passage 132, which is paired up with the main body upper flow passage 132 supplying coolant, allows coolant supplied to the VCSEL module 200 to flow back through the module supporting plate 100.

The main body lower flow passage 133 extends vertically inside the support main body plate 110 and extends downward from the main body internal flow passage 131. An upper end of the main body lower flow passage 133 is connected to the main body internal flow passage 131, and a lower end may be opened to the lower surface of the support main body plate 110. The main body lower flow passage 133 provides a passage through which coolant flows. The main body lower flow passage 133 may provide a flow passage through which coolant flows into the main body lower flow passage 133 from the outside, and a flow passage through which coolant flows out to the outside. The main body lower flow passage 133 may be formed at one end or the other end of the main body internal flow passage 131. Unlike the main body upper flow passage 132, one main body lower flow passage 133 may be formed for each main body internal flow passage 131.

The main body lower flow passage 133 may connect the main body internal flow passage 511 and the coolant inlet tube 134 or the coolant outlet tube 135. Therefore, the main body lower flow passage 133 provides a passage through which coolant in the coolant inlet tube 134 flows into the main body internal flow passage 131. In addition, the main body lower flow passage 133 provides a passage through which coolant in the main body internal flow passage 131 flows out to the coolant outlet tube 135.

The coolant inlet tube 134 may be formed from a general metal tube through which coolant may flow. The coolant inlet tube 134 may be coupled to the main body lower flow passage 133. The coolant inlet tube 134 may provide a passage through which coolant is supplied to the main body lower flow passage 133.

The coolant outlet tube 135 may be formed as a general metal tube through which coolant flows. The coolant outlet tube 135 may be coupled to the main body lower flow passage 133. The coolant outlet tube 135 may provide a passage through which coolant flows out from the main body lower flow passage 133.

The VCSEL module 200 may include a device substrate 210, a VCSEL device 220, a terminal pad 230, and a cooling block 240. Meanwhile, the VCSEL module 200 may be formed from a laser source device that irradiates a laser beam, instead of the VCSEL device 220. In this case, the VCSEL module 200 may be referred to as a laser source module. Therefore, in the present disclosure, the VCSEL module 200 and the VCSEL device 220 are used as concepts including a laser source module and a laser source device, respectively. In addition, the laser source device may include a surface light emitting device or an edge light emitting device.

The plurality of VCSEL modules 200 may be arranged and placed on an upper surface of the module supporting plate 100 in a lattice shape. The VCSEL modules 200 may be placed on the unit module region 100a of the upper surface of the module support plate 100, respectively. The VCSEL module 200 may irradiate a laser beam emitted from the VCSEL device 220 to the flat substrate. The VCSEL module 200 may be arranged on a region required to irradiate a laser beam to an irradiation region of the flat substrate being heated. The VCSEL module 200 may be formed to have various areas and shapes depending on the area and shape of the irradiation region. In addition, the VCSEL module 200 may be formed to have an appropriate area and shape depending on the number thereof to be used.

Meanwhile, here, referring to the configuration in FIG. 2, the x-axial direction is expressed as one side and the other side or one end and the other end, and the y-axial direction is expressed as a front side and a rear side or a front end and a rear end. In addition, the x-axial direction is expressed as a width or a width direction, and the y-axial direction is expressed as length or a length direction.

The VCSEL module 200 may include a device region 200a in which the VCSEL device 220 is mounted, and a terminal region 200b in which the electrode terminal 400 is coupled. In the VCSEL module 200, the device region 200a and the terminal region 200b may be arranged in various shapes and positions depending on a planar shape and a structure placed on the module support plate 100. For example, the device region 200a may be formed in a quadrangular shape, and the terminal region 200b may be formed to protrude on the other side of a front end and one side of a rear end of the device region 200a. The terminal region 200b may be formed on a half region of the other side direction at the front end of the device region 221a and on a half region of one side direction at the rear end of the device region 221a. That is, the terminal region 200b may be formed to have a width corresponding to half of the width of the device region 200a.

In addition, when the VCSEL module 200 is arranged on the module support plate 100 in the y-axial direction, the terminal region 200b positioned at the other side of the front end and the terminal region 200b positioned at one side of the rear end of the adjacent VCSEL module 200 may be placed adjacent to each other in the x-axial direction. In the sub-irradiation module 220, the device regions 200a and the terminal regions 200b may be linearly arranged in the x-axial direction, respectively, and the device regions 200a and the terminal regions 200b may be alternately arranged in the y-axial direction. The sub-irradiation modules 220 may be disposed such that a pitch between the sub-irradiation modules 220 adjacent to each other in the y-axial direction and the x-axial direction is minimized. In addition, the sub-irradiation modules 220 may be arranged to have a pitch therebetween of up to 2 mm.

In the VCSEL module 200, the VCSEL devices 220 may be arranged on the device region 200a in the x-axial direction and the y-axial direction to be arranged in a lattice shape. In addition, in the VCSEL module 200, electrode pads are placed on the terminal region 200b. In the VCSEL module 200, the electrode pad and the VCSEL device 220 are electrically connected to each other, and it is possible to supply an electric power from the electrode pad to the VCSEL device 220. In the VCSEL module 200, although not specifically illustrated, the electrode pad and the VCSEL device 220 may be electrically connected to each other by a plurality of electrically conductive patterns provided on the device substrate 210.

The device substrate 210 may be formed of a general substrate used to mount electronic devices. For example, the device substrate 210 may be a PCB board or a ceramic board. The device substrate 210 may be divided into the device region 200a on which the VCSEL device 220 is mounted and the terminal region 200b on which the terminal pad 230 placed. Here, the device region 200a and the terminal region 200b have the same concept as the device region 200a and the terminal region 200b of the VCSEL module 200 described above.

The device substrate 210 may have a device terminal hole 211. The device terminal hole 211 may be formed by penetrating the terminal region 200b of the device substrate 210 from an upper surface to a lower surface. The device terminal hole 211 may be in communication with the support terminal hole 111 of the module support plate 100. The device terminal holes 211 may be formed in pairs and spaced apart from each other in one terminal region 200b. The device terminal holes 211 may include the device terminal hole 211 through which a positive electrode terminal passes and the device terminal hole 211 through which a negative electrode terminal passes.

The VCSEL device 220 may be formed of a general VCSEL device 222 irradiating a laser beam. For example, the VCSEL device 220 may be a device that oscillates a surface-emitting laser. The VCSEL device 220 may be formed to have a quadrangular planar shape, preferably a square shape or a rectangular shape in which the ratio of width to length does not exceed 1:2. The VCSEL device 220 is manufactured of a cubic-shaped chip, and a high-power laser beam is oscillated from one surface. Since the VCSEL device 220 oscillates a high-power laser beam, as compared to a conventional halogen lamp, this device may heat the flat substrate efficiently and has a relatively long lifespan.

On the device region 200a, the plurality of the VCSEL devices 220 may be arranged on an upper surface of the device substrate 220 in the x-axial direction and the y-axial direction to be arranged in a lattice shape. An appropriate number of the VCSEL devices 220 may be placed at appropriate intervals depending on the area of the device region 200a and the required amount of energy of a laser beam. In addition, the VCSEL devices 220 may be placed at an interval such that uniform energy may be irradiated when a laser beam emitted from one VCSEL device overlaps a laser beam of the adjacent VCSEL device 220.

The terminal pad 230 may be formed as a ring-shaped pad extending along an outer periphery of an upper end of the device terminal hole 211 formed on the terminal region 200b of the device substrate 210. In each terminal region 200b, accordingly, the terminal pad 230 may correspond to the device terminal hole 211, thereby being formed in pairs. The terminal pads 230 may be used as the (+) terminal pad 230 and the (−) terminal pad 230. The terminal pads 230 may be electrically connected to the VCSEL devices 220, 222. As mentioned above, the terminal pad 230 is electrically connected to the electrically conductive pattern formed on the upper surface of the device substrate 210, and may be electrically connected to the VCSEL device 220. The terminal pad may supply an electric power necessary for driving the VCSEL device 220. The terminal pad 230 may be formed of a general pad formed on the substrate. The terminal pad 230 may be made from a metal such as copper, having excellent electrical conductivity.

The cooling block 240 may include a block terminal hole 241 and a block cooling flow passage 242. The cooling block 240 may be formed to have a planar shape, corresponding to a planar shape of the device substrate 210, and a predetermined height. The cooling block 240 may be made of a ceramic material or a metallic material having thermal conductivity. The cooling block 240 may be coupled to a lower surface of the device substrate 210 by a separate adhesive layer 250. The cooling block 240 may dissipate heat, which is generated from the VCSEL device 220 mounted on the device substrate 210, downward. Thus, the cooling block 240 may cool the device substrate 210 and the VCSEL device 220.

The block terminal hole 241 may be formed by penetrating the cooling block 240 from an upper surface to a lower surface thereof. The block terminal hole 241 may be formed at a position corresponding to the device terminal hole 211 of the device substrate 210. Accordingly, the block terminal holes 241 are formed in one pair on the terminal region 200b and may be in communication with the device terminal holes 211, respectively. The block terminal hole 241 may provide a passage through which the electrode terminal 400 passes. That is, the block terminal holes 241 may provide passages through which the positive electrode terminal and the negative electrode terminal pass.

The block cooling flow passage 242 may be composed of a block inlet 242a and a block outlet 242b formed in the lower surface of the cooling block 240, and various shaped block internal flow passages 242c formed inside the cooling block 240. For example, the block cooling flow passage 242 may include two vertical flow passages extending upward from the lower surface and one horizontal flow passage connecting the vertical flow passages. The block cooling flow passage 242 may be formed to have “∩”-shaped vertical cross-section. Two or more block cooling flow passages 242 may be formed depending on a size of the cooling block 240. The block cooling flow passage 242 is connected to the main body upper flow passage 132 of the support main body plate 110, and allows coolant to flow thereinto to cool the cooling block 240.

The electric power supplying board 300 may include an electric power terminal hole 310 and an electric power protrusion hole 320. The electric power supplying board 300 may further include a fixed connector 330 and a connecting connector 340. Although not specifically shown, various electrically conductive patterns for supplying an electric power may be formed on upper and lower surfaces of the electric power supplying board 300.

The electric power supplying board 300 may be formed in a planar shape corresponding to the shape of the module support plate 100. The electric power supplying board 300 may be formed of a conventional board. For example, the electric power supplying board 300 may be formed of a printed circuit board (PCB) or a ceramic board. The electric power supplying board 300 is placed below the module support plate 100, is electrically connected to the VCSEL module 200 through the electrode terminal 400, and may supply the electric power to the VCSEL device 220.

The electric power terminal hole 310 is formed by penetrating the electric power supplying board 300 from the upper surface to the lower surface. The electric power terminal hole 310 is formed at a position where corresponds to the support terminal hole 111 of the module support plate 100 when the electric power supplying board 300 is coupled to a lower portion of the module support plate 100. Thus, the electric power terminal hole 310 may be in communication with the support terminal hole 111. The electric power terminal holes 310 may correspond to the support terminal holes 111, thereby being formed in one pair.

The electric power terminal hole 310 may provide a passage through which the electrode terminal 400 passes. Accordingly, the electric power terminal hole 310 may be formed with an inner diameter corresponding to an outer diameter of the electrode terminal 400. One of the electric power terminal holes 310 may allow a positive electrode terminal to pass therethrough and the other may allow a negative electrode terminal to pass therethrough.

The electric power protrusion hole 320 is formed to penetrate the electric power supplying board 300 from the upper surface to the lower surface. The electric power protrusion hole 320 is formed at a position corresponding to a position of the support lower protrusion 120 of the module support plate 100 when the electric power supplying board 300 is coupled to a lower portion of the module support plate 100. Therefore, the electric power protrusion hole 320 may provide a passage through which the support lower protrusion 120 passes. The electric power protrusion hole 320 may correspond to the lower support protrusion 120 to be formed in one pair. The electric power protrusion hole 320 is coupled to the support lower protrusion 120, and may allow the support lower protrusion 120 to be coupled from an upper portion to a lower portion, so as to protrude downward.

The fixed connector 330 is coupled to the electric power supplying board and may be electrically connected to the electric power supplying board. The fixed connector 330 supplies an electric power supplied from the outside to the electric power supplying board 300 to allow electric power to be supplied to the VCSEL device 220. The fixed connector 330 may be electrically connected to various electrically conductive patterns formed on the electric power supplying board 300. As the fixed connector 330, a conventional connector used in the substrate may be employed. The plurality of fixed connectors 330 may be provided depending on the area of the electric power supplying board 300, the number of the VCSEL devices 220, and an arrangement relation.

The connecting connector 340 is detachably coupled to the fixed connector 330 and may be electrically connected to the fixed connector 330. The connecting connector 340 may supply an electric power supplied from the outside to the fixed connector 330. As the connecting connector 340, a conventional connector used in the substrate may be employed.

The electrode terminal 400 may include an upper terminal bolt 410, a lower terminal bold 420, a connection nut 430 and an insulating tube 440.

The electrode terminal 400 electrically connects the VCSEL module 200 and the electric power supplying board 300 while being inserted into the module support plate 100 from an upper portion of the VCSEL module 200 and a lower portion of the electric power supplying board 300. In addition, the electrode terminal 400 independently secures each VCSEL module 200 to the module support plate 100. Furthermore, since the electrode terminal 400 is coupled in a bolt-nut manner, it is easy to couple and detach the terminal electrode. Therefore, when the specific VCSEL module 200 is broken, the VCSEL module 200 can be replaced by detaching only the electrode terminal 400 securing the problematic VCSEL module 200.

The upper terminal bolt 410 may be formed of a conventional bolt provided with an upper body part having a threaded section formed on a lower portion thereof and an upper head part coupled to an upper portion of the upper body part. In the upper terminal bolt 410, the upper body part passes through the device terminal hole 211 and the block terminal hole 241 of the VCSEL module 200 and is then inserted into the support terminal hole 111. Therefore, the upper body part of the upper terminal bolt 410 may be formed with a length such that the threaded section formed on the lower portion may be placed at an appropriate position in the support terminal hole 111 of the module support plate 100.

The upper terminal bolt 420 may be made from an electrically conductive material. For example, the upper terminal bolt 410 may be made from a metallic material. The upper terminal bolt 410 may be made from a stainless-steel material, a cooper material, or an aluminum material. The upper terminal bolt 420 may be electrically connected to the terminal pad 230. More specifically, a lower surface of the upper head part is seated on the upper surface of the device substrate 210 of the VCSEL module 200, and may be electrically connected to the terminal pad 230. The upper head part comes in direct contact with an upper surface of the terminal pad 230. Accordingly, the upper terminal bolt 410 is electrically connected to the VCSEL device 220 via the terminal pad 230.

The lower terminal bolt 420 may be formed of a conventional bolt provided with a lower body part with a threaded section formed on a lower portion thereof and a lower head part coupled to an upper portion of the lower body part. The lower terminal bolt 420 may be formed of the same bolt as the upper terminal bolt 410. However, since the lower terminal bolt 420 is inserted into the module support plate 100 from a lower side through the relatively thin electric power supplying board 300, the length of the lower terminal bolt may be relatively short. The lower terminal bolt 420 may be made from an electrically conductive material. For example, the lower terminal bolt 420 may be made from a metallic material. The lower terminal bolt 420 may be made from a stainless-steel material, a cooper material, or an aluminum material.

In the lower terminal bolt 420, the lower body part passes through the electric power terminal hole 310 of the electric power supplying board 300 and is then inserted into the support terminal hole 111. The lower terminal bolt 420 may be electrically connected to the electric power supplying board 300. More specifically, a lower surface of the lower head part may come in contact with the lower surface of the electric power supplying board 300. Accordingly, the lower terminal bolt 420 may be electrically connected to the electrically conductive pad formed on the lower surface of the electric power supplying board 300. Accordingly, the lower terminal bolt 420 may supply electric power, which is being supplied to the electric power supplying board 300, to the upper terminal bolt 410.

The connecting nut 430 has a tube shape with opened upper and lower end portions, and a threaded section may be formed on an inner circumferential surface thereof in its entirety. The connecting nut 430 may be formed with a length longer than at least half of a thickness of the module support plate 100. In addition, the connecting nut 430 is formed to have an outer diameter smaller than an inner diameter of the support terminal hole 111. The connecting nut 430 is inserted into the support terminal hole 111. The connecting nut 430 may be positioned inside the support terminal hole 111 so that its lower end portion coincides with a lower end portion of the support terminal hole 111. The connecting nut 430 may be inserted such that its upper end portion is located above a midpoint of the support terminal hole 111.

Therefore, the connecting nut 430 is placed inside the support terminal hole 111, the upper terminal bolt 410 is screw-coupled to the upper portion of the connecting nut and the lower terminal bolt 420 is screw-coupled to the lower portion. The connecting nut 430 may be formed with a length which is necessary for screw-coupling the upper terminal bolt 410 and the lower terminal bolt 420. The connecting nut 430 may be formed of an electrically conductive material. For example, the connecting nut 430 may be formed of a metal material. The connecting nut 430 may be formed of a stainless-steel material, a copper material, or an aluminum material.

While screw-coupled with the upper terminal bolt 410 and the lower terminal bolt 420, the connecting nut 430 allows the upper head part of the upper terminal bolt 410 to be pressed against the terminal pad 230 of the VCSEL module 200, and allows the lower head part of the lower terminal bolt 420 to be pressed against the lower surface of the electric power supplying board. In addition, since the connecting nut 430 is screw-coupled with the upper terminal bolt 410 and the lower terminal bolt 420, it allows the upper terminal bolt 410 or the lower terminal bolt 420 to be more easily detached. In addition, the connecting nut 430 electrically connects the upper terminal bolt 410 and the lower terminal bolt 420.

The insulating tube 440 may be formed in a tube shape in which an inner circumferential surface corresponds to an outer circumferential surface of the connecting nut 430. The insulating tube 440 is formed of an electric insulator. For example, the insulating tube 440 may be formed of a resin material. The insulating tube 440 is placed between an outer circumferential surface of the connecting nut 430 and an inner circumferential surface of the support terminal hole 111 to electrically insulate the connecting nut 430 and the module support plate 100. In addition, the insulating tube 440 is placed between an outer circumferential surface of the upper terminal bolt 410, which is exposed to the upper portion of the connecting nut 430, and an inner circumferential surface of the support terminal hole 111 to electrically insulate the upper terminal bolt 410 and the module support plate 100. In this case, the insulating tube 440 may be formed such that a portion thereof which is in contact with the insulating support ring has a relatively small diameter.

Next, an operation of the flat-substrate heating apparatus using the VCSEL module according to one embodiment of the present disclosure is described.

In the flat-substrate heating apparatus 10 of the present disclosure, the VCSEL module 200 is placed on the upper surface of the module support plate 100, and the electric power supplying substrate 300 is placed below the module support plate 100. The upper terminal bolt 410 of the electrode terminal 400 passes through the device terminal hole 211 and the block terminal hole 241 of the VCSEL module 200 from the above to be inserted into the support terminal hole 111 of the module support plate 100. In addition, the connecting nut 430 is first inserted and positioned inside the module support plate 100. Therefore, the upper terminal bolt 410 may be screw-coupled to the connecting nut 430 to secure the VCSEL module 200 to the module support plate 100. Each of the VCSEL modules 200 is independently mounted on the module support plate 100, and may be secured to the module support plate 100 by upper terminal bolt 410. The lower terminal bolt 420 of the electrode terminal 400 passes through the electric power terminal hole 310 of the electric power supplying board 300 below the module support plate 100, and is then screw-coupled with the connecting nut 430 of the support terminal hole 111 of the module support plate 100 to enable the electric power supplying board 300 to be secured to a lower surface of the module support plate 100. At this time, the upper surface of the electric power supplying substrate 300 is spaced apart from the lower surface of the module support plate 100 to enable a plurality of electrically conductive patterns, which are formed on the upper surface, to be electrically insulated from the lower surface of the module support plate 100.

Since the upper terminal bolt 410 is electrically connected to the VCSEL module 200 and the lower terminal bolt 420 is electrically connected to the electric power supplying board 300 and is coupled to the connecting nut 430 together with the upper terminal bolt, the electrode terminal 400 may electrically connect the VCSEL module 200 and the electric power supplying board 300. At this time, since the insulating tube 440 is placed between an inner circumferential surface of the support terminal hole 111 of the module support plate 100 and the connecting nut 430, the electrode terminal 400 is not electrically connected to the module support plate 100. The insulating tube 440 may also be placed between the upper terminal bolt 410 and an inner circumferential surface of the support terminal hole 111.

In addition, in the flat-substrate heating apparatus 10, coolant supplied from the outside may cool heat generated from the VCSEL device 220 while flowing to the main body lower flow passage 133 and the main body internal flow passage 131 of the support main body plate 110 through the coolant inlet tube 135 and flowing to the block cooling flow passage 242 of the VCSEL module 200 through the main body upper flow passage 132. Again, coolant flows out to a coolant discharging tube 530 through the main body upper flow passage 132, the main body internal flow passage 131, and the main body lower flow passage 133 of the support main body plate 110. Therefore, in the flat-substrate heating apparatus 10, the flow passage for supplying coolant to each VCSEL module 200 is provided, so it is possible to independently separate the broken VCSEL module 200.

In order to help those skilled in the art to understand, the most preferred embodiments are selected from the various implementable embodiments of the present disclosure, and are set forth in the present specification. In addition, the technical spirit of the present disclosure is not necessarily restricted or limited only by these embodiments, and various changes, additions, and modification are possible without departing from the technical spirit of the present disclosure, and implementations of other equivalent embodiments are possible.

1. A flat substrate heating apparatus, comprising:
a module supporting plate having a plurality of unit module regions formed on an upper surface thereof;
a plurality of VCSEL modules having a plurality of VCSEL devices and seated on the unit module regions of the module support plate, respectively;
an electric power supplying board placed below the module support plate and configured to supply an electric power to the VCSEL module; and
an electrode terminal electrically connecting the VCSEL module and the electric power supplying board while detachably securing them to upper and lower surfaces of the module support plate,
wherein the module support plate has a coolant supplying unit formed therein and configured to supply coolant to the VCSEL module.

2. The flat-substrate heating apparatus of claim 1, wherein the VCSEL module comprises:
a device substrate having a device region, a terminal region, and a device terminal hole passing through the terminal region from an upper surface to a lower surface of the terminal area;
a VCSEL device arranged on the device region of the device substrate;
a terminal pad formed in a ring shape extending along an outer periphery of an upper end of the device terminal hole; and
a cooling block placed below the device substrate and having a block terminal hole.

3. The flat-substrate heating apparatus of claim 2, wherein the module support plate has a support main body plate having a support terminal hole formed at a position corresponding to the device terminal hole in the unit module region, the electric power supplying board has an electric power terminal hole formed at a position corresponding to the support terminal hole, and the electrode terminal comprises an upper terminal bolt passing through the device terminal hole and the block terminal hole to be inserted into an upper portion of the support terminal hole, a lower terminal bolt passing through the electric power terminal hole to be inserted into a lower portion of the support terminal hole, and a connecting nut placed inside the support terminal hole to be screw-coupled with the upper terminal bolt and the lower terminal bolt.

4. The flat-substrate heating apparatus of claim 3, wherein the upper terminal bolt is electrically connected to the terminal pad, and the lower terminal bolt is electrically connected to the electric power supplying board.

5. The flat-substrate heating apparatus of claim 3, wherein the electrode terminal further comprises an insulating tube placed between an inner circumferential surface of the support terminal hole and an outer circumferential surface of the connecting nut.

6. The flat-substrate heating apparatus of claim 3,
wherein the coolant supplying unit comprises:
a main body internal flow passage formed to extend horizontally in a x-axial direction or a y-axial direction within the support main body plate;
a main body upper flow passage extending vertically within the support main body plate, a lower end of which being connected to the main body internal flow passage and an upper end of which being is opened to an upper surface of the support main body plate; and
a main body lower flow passage extending vertically within the support main body plate, an upper end of which being connected to the main body internal passage, and a lower end of which being opened to a lower surface of the support main plate,
wherein the cooling block further comprises a block cooling flow passage being in communication with the main body upper flow passage, and is formed such that coolant for cooling the VCSEL device flows through the main body upper flow passage and the block cooling flow passage.

7. The flat-substrate heating apparatus of claim 6, wherein the coolant supplying unit further comprises a coolant inlet tube for supplying coolant to the main body lower flow passage, and a coolant outlet tube for discharging coolant from the main body lower flow passage.

8. The flat-substrate heating apparatus of claim 7, wherein the support main body plate further comprises a connecting flow passage connecting the main body internal flow passages when the plurality of main body internal flow passages are formed in plurality of pairs.
